(19) United States
(12) Patent Application Publication
(10) Pub. No.: US 2013/0083484 A1
(43) Pub. Date: Apr. 4, 2013

(54) COMPOSITE ELECTRONIC COMPONENT AND STRUCTURE FOR MOUNTING COMPOSITE ELECTRONIC COMPONENT

(71) Applicant: TDK Corporation, Tokyo (JP)

(72) Inventor: Masaaki TOGASHI, Tokyo (JP)

(73) Assignee: TDK CORPORATION, Tokyo (JP)

(21) Appl. No.: 13/626,583

(22) Filed: Sep. 25, 2012

(30) Foreign Application Priority Data
Oct. 3, 2011 (JP) 2011-219137

(51) Int. Cl. H05K 7/02; H05K 7/20

(52) U.S. Cl. 361/699; 361/809; 361/760; 361/782

(57) ABSTRACT

A composite electronic component includes electronic components, a conductor layer, and a support. Each of the electronic components includes a first terminal electrode and a second terminal electrode that are arranged on respective opposing surfaces of an element body. The conductor layer electrically connects the first terminal electrodes of the electronic components to one another. The conductor layer is arranged on the support. The second terminal electrodes of the electronic components function as mounting terminal electrodes to be connected to terminals of a circuit substrate.

### CROSS-REFERENCE TO RELATED APPLICATIONS

This application is based upon and claims the benefit of priority from Japanese Patent Application No. 2011-219137, filed on Oct. 3, 2011, the entire contents of which are incorporated herein by reference.

### BACKGROUND OF THE INVENTION

1. Field of the Invention

The present invention relates to a composite electronic component including a plurality of electronic components and to a structure for mounting the composite electronic component.

2. Description of the Related Art

There is a known composite electronic component, in which a plurality of electronic components are integrated so as to function as one electronic component. For example, Japanese Patent Application Laid-open No. 2004-40083 discloses an electronic assembly including a mechanical support structure that separates a plurality of discrete passive components from one another and that includes a structure for protecting the discrete passive components.

In the electronic assembly (corresponding to a composite electronic component) disclosed in Japanese Patent Application Laid-open No. 2004-40083, each of the discrete passive components (corresponding to electronic components) is independently combined, and therefore, each of the electronic components is independently mounted on a circuit substrate. The technology disclosed in Japanese Patent Application Laid-open No. 2004-40083 has a problem in that, when a defect occurs in any of the electronic components, the reliability is reduced because the other electronic components cannot compensate for the functions of the defected electronic component.

### SUMMARY OF THE INVENTION

According to a first aspect of the present invention, there is provided a composite electronic component including: a plurality of electronic components, each including a first terminal electrode and a second terminal electrode that are arranged on respective opposing surfaces of an element body; a conductor layer for electrically connecting the first terminal electrodes of the electronic components to one another; and a support on which the conductor layer is formed, wherein the second terminal electrodes of the electronic components function as mounting terminal electrodes to be connected to terminals of a circuit substrate.

According to a second aspect of the present invention, there is provided a mounting structure of a composite electronic component, the composite electronic component including: a plurality of electronic components each including a first terminal electrode and a second terminal electrode that are arranged on respective opposing end surfaces of an element body; a conductor layer for electrically connecting the first terminal electrodes of the electronic components to one another; and a support on which the conductor layer is arranged, wherein the electronic components are connected to terminals of a circuit substrate such that the polarities of the second terminal electrodes become opposite to each other.

### BRIEF DESCRIPTION OF THE DRAWINGS

FIG. 1 is a plan view of a composite electronic component according to a first embodiment;

FIG. 2 is a diagram viewed in the direction of arrow A-A in FIG. 1;

FIG. 3 is a perspective view of an electronic component included in the composite electronic component according to the first embodiment;

FIG. 4 is a diagram illustrating an equivalent circuit of the composite electronic component according to the first embodiment;

FIG. 5 is a diagram illustrating a mounting structure of the composite electronic component according to the first embodiment;

FIG. 6 is a diagram for explaining the polarities of terminal electrodes mounted on the composite electronic component in a mounting structure according to a first modification of the first embodiment;

FIG. 7 is a diagram for explaining the polarities of the terminal electrodes mounted on the composite electronic component in the mounting structure according to the first modification of the first embodiment;

FIG. 8 is a diagram illustrating the mounting structure according to the first modification of the first embodiment;

FIG. 9 is a diagram illustrating an equivalent circuit in the mounting structure according to the first modification of the first embodiment;

FIG. 10 is a plan view of a composite electronic component according to a second modification of the first embodiment;

FIG. 11 is a diagram viewed in the direction of arrow B-B in FIG. 10;

FIG. 12 is a perspective view of an electronic component included in the composite electronic component according to the second modification of the first embodiment;

FIG. 13 is a plan view of a composite electronic component according to a third modification of the first embodiment;

FIG. 14 is a diagram viewed in the direction of arrow C-C in FIG. 13;

FIG. 15 is a cross-sectional view illustrating an example of an electronic component included in the composite electronic component according to the third modification of the first embodiment;

FIG. 16 is a partial cross-sectional view illustrating an example in which a different electronic component is applied to the composite electronic component according to the third modification of the first embodiment;

FIG. 17 is a cross-sectional view of the electronic component illustrated in FIG. 16;

FIG. 18 is a plan view of a composite electronic component according to a fourth modification of the first embodiment;

FIG. 19 is a diagram viewed in the direction of arrow D-D in FIG. 18;

FIG. 20 is a diagram illustrating an equivalent circuit of the composite electronic component according to the fourth modification of the first embodiment;

FIG. 21 is a diagram illustrating a mounting structure according to the fourth modification of the first embodiment;

FIG. 22 is a plan view of a composite electronic component according to a second embodiment;

FIG. 23 is a diagram viewed in the direction of arrow E-E in FIG. 22;

FIG. 24 is a diagram illustrating a composite electronic component and a mounting structure according to a third embodiment;

FIG. 25 is a plan view of a composite electronic component according to a fourth embodiment;

FIG. 26 is a diagram viewed in the direction of arrow F-F in FIG. 24;

FIG. 27 is a diagram illustrating an equivalent circuit of the composite electronic component according to the fourth embodiment;

FIG. 28 is a plan view of a composite electronic component according to a first modification of the fourth embodiment;

FIG. 29 is a diagram illustrating an equivalent circuit of the composite electronic component according to the first modification of the fourth embodiment;

FIG. 30 is a plan view of a composite electronic component according to a second modification of the fourth embodiment;

FIG. 31 is a plan view illustrating a configuration of a conductor layer included in the composite electronic component according to the second modification of the fourth embodiment;

FIG. 32 is a diagram viewed in the direction of arrow G-G in FIG. 30;

FIG. 33 is a diagram illustrating an equivalent circuit of the composite electronic component according to the second modification of the fourth embodiment;

FIG. 34 is a diagram illustrating an equivalent circuit of another filter;

FIG. 35 is a plan view of a composite electronic component according to a third modification of the fourth embodiment;

FIG. 36 is a diagram illustrating an electronic component included in the composite electronic component according to the third modification of the fourth embodiment;

FIG. 37 is a diagram illustrating an electronic component included in the composite electronic component according to the third modification of the fourth embodiment; and

FIG. 38 is a diagram illustrating an equivalent circuit according to a modification of the electronic component group included in the composite electronic component of the fourth embodiment.

### DETAILED DESCRIPTION OF THE PREFERRED EMBODIMENTS

Embodiments of the present invention aim to improve the reliability of the composite electronic component including a plurality of electronic components.

Embodiments of the present invention will be described in detail below with reference to the accompanying drawings. The present invention is not limited by the descriptions of the embodiments below. The components described in the embodiments include those that one skilled in the art could readily conceive and those substantially identical. The components described in the embodiments can be combined appropriately. Any of the components can be omitted, replaced, or modified within the sprit and scope of the present invention.

### First Embodiment

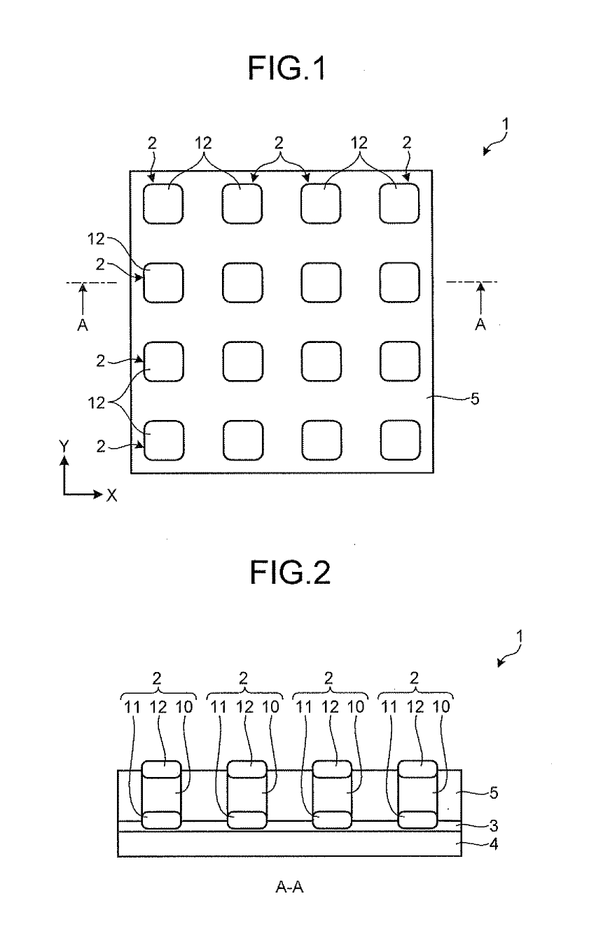

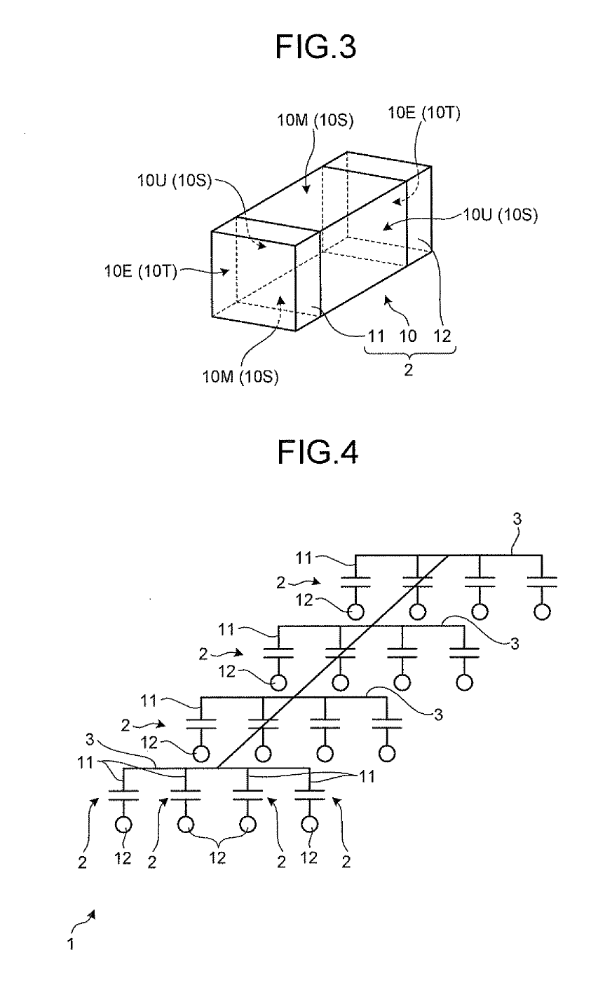

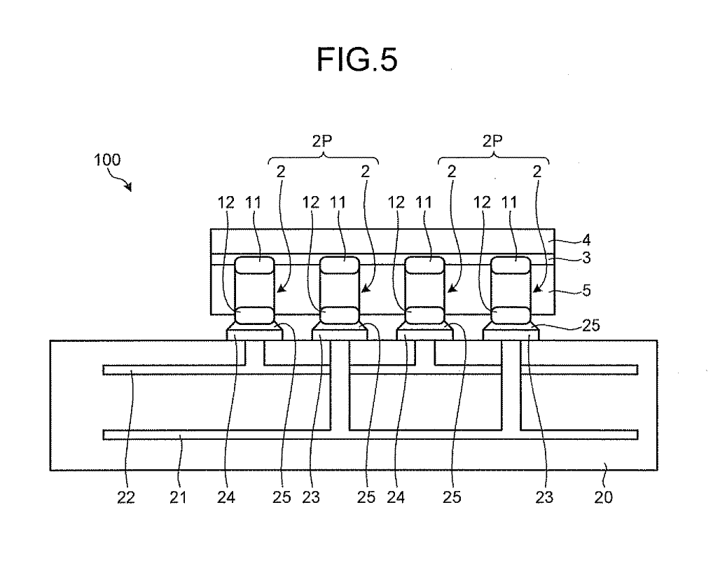

FIG. 1 is a plan view of a composite electronic component according to a first embodiment. FIG. 2 is a diagram viewed in the direction of arrow A-A in FIG. 1. FIG. 3 is a perspective view of an electronic component included in the composite electronic component according to the first embodiment. FIG. 4 is a diagram illustrating an equivalent circuit of the composite electronic component according to the first embodiment. FIG. 5 is a diagram illustrating a mounting structure of the composite electronic component according to the first embodiment. A composite electronic component 1 includes a plurality of electronic components 2, a conductor layer 3, and a support 4. In the first embodiment, the composite electronic component 1 further includes an insulating member 5. However, the insulating member 5 is not necessarily needed.

The composite electronic component 1 includes 16 electronic components 2. However, the number of the electronic components 2 is not specifically limited; for example, the number may be odd. As illustrated in FIG. 2 and FIG. 3, each of the electronic components 2 includes an element body 10, a first terminal electrode 11 and a second terminal electrode 12. The element body 10 is a ceramic element body that includes an inner electrode or an inner conductor and a dielectric. The element body 10 is, for example, a ceramic element body including an inner electrode layer and a dielectric layer.

The element body 10 has an approximately cuboid shape and includes, as outer surfaces, first and second principal surfaces 10M, 10M opposing each other, first and second end surfaces 10E, 10E opposing each other, and first and second side surfaces 10U, 10U opposing each other. The first and second end surfaces 10E, 10E extend along the short-side direction of the first and second principal surfaces 10M, 10M so as to connect the first and second principal surfaces 10M, 10M, each of which has an approximately rectangular shape. The first and second side surfaces 10U, 10U extend along a long-side direction of the first and second principal surfaces 10M, 10M so as to connect the first and second principal surfaces 10M, 10M, each of which has an approximately rectangular shape.

In the first embodiment, the first and second end surfaces 10E, 10E have an approximately square shape in a plan view. The first and second end surfaces 10E, 10E correspond to two short-side surfaces 10T. The first and second principal surfaces 10M, 10M and the first and second side surfaces 10U, 10U have an approximately rectangular shape in a plan view, and correspond to four long-side surfaces 10S. The shape of the element body 10 is not limited to the above. If the element body 10 is formed of the inner electrode layer and the dielectric layer, the inner electrode layer and the dielectric layer are laminated so as to be approximately parallel to the first and second end surfaces 10E, 10E and the first and second side surfaces 10U, 10U, and so as to be orthogonal to the principal surfaces 10M.

Each of the electronic components 2 includes the first terminal electrode 11 and the second terminal electrode 12 on the respective opposing surfaces (in the first embodiment, the short-side surfaces 10T, 10T) of the element body 10. The first terminal electrode 11 and the second terminal electrode 12 cover the whole of the short-side surfaces 10T, 10T and parts of the four long-side surfaces 10S. In general, the electronic component 2 as described above is an electronic component of a type called a chip electronic component, which is a surface-mount electronic component that is mountable on the surface of a circuit substrate. In the first embodiment, the second terminal electrodes 12 of the electronic components 2 serve as mounting terminal electrodes to be electrically connected to first substrate terminals 23 and second substrate terminals 24 of a circuit substrate 20 illustrated in FIG. 5, and the first terminal electrodes 11 of the electronic components 2 are electrically connected to the conductor layer 3.

In the first embodiment, all of the electronic components 2 are capacitor elements (for example, chip capacitors). Each of the capacitor elements is a laminated element, in which two or more electrodes provided inside the element body 10 (inner electrodes) and the dielectric are laminated such that one of the inner electrodes sandwiching the dielectric is electrically connected to the first terminal electrode 11 and the other one of the inner electrodes is electrically connected to the second terminal electrode 12. The composite electronic component 1 includes a plurality of capacitor elements as the electronic components, so that the composite electronic component 1 functions as a capacitor. The type of the electronic components 2 included in the composite electronic component 1 is not limited to the capacitor element, but may be a resistor element, an inductor element, a varistor element, or the like. The electronic components 2 included in the composite electronic component 1 may be of the same type or of different types.

The conductor layer 3 may be, for example, a conductive adhesive material or a conductive resin, and the former is used in the first embodiment. As illustrated in FIG. 2, the conductor layer 3 electrically connects the first terminal electrodes 11 of the electronic components 2. The support 4 is, in the first embodiment, a plate-like member having a rectangular shape (including a square) in a plan view. In the first embodiment, the support 4 may be a conductor or an insulator. In general, a conductor is a good conductor of heat; therefore, if a conductor is used as the support 4, it becomes possible to efficiently transfer the heat of the electronic components 2 of the composite electronic component 1 into the atmosphere.

If an insulator is used as the support 4, it becomes possible to electrically isolate the first terminal electrodes 11 and the support 4. Therefore, it becomes possible to prevent short circuit between the electronic components 2 and a casing housing the circuit substrate 20 or between the electronic components 2 and other electronic components mounted on the circuit substrate 20, via the support 4. In some cases, an electromagnetic shield layer may be formed by coating the surface of the composite electronic component 1 excluding a portion opposing the circuit substrate 20 with a conductor. If an insulator is used as the support 4, it becomes possible to prevent short circuit between the electronic components 2 and the casing housing the circuit substrate 20 or between the electronic components 2 and other electronic components mounted on the circuit substrate 20, via the support 4 and the electromagnetic shield layer.

The conductor layer 3 is provided on the support 4. Specifically, the conductor layer 3 is provided on one of the two surfaces with the largest area (a conductor layer arrangement surface) among the surfaces of the support 4. With this structure, the electronic components 2, the first terminal electrodes 11 of which are electrically connected by the conductor layer 3, are supported by the support 4.

In the first embodiment, the insulating member 5 is an insulating resin; however, it is not limited thereto. The insulating member 5 is in contact with the conductor layer 3 and is fixed and supported on the support 4 via the conductor layer 3. The insulating member 5 is arranged around the electronic components 2 of the composite electronic component 1. With this structure, the insulating member 5 is arranged between the adjacent electronic components 2. The second terminal electrodes 12 of the electronic components 2 protrude from the surface of the insulating member 5. The second terminal electrodes 12 are arranged such that portions that cover the whole of the short-side surfaces 10T of the element bodies 10 are on approximately the same plane. With this arrangement, when the composite electronic component 1 is mounted on the circuit substrate 20 illustrated in FIG. 5, it is possible to maintain an approximately constant distance between each of the first substrate terminals 23 and the second substrate terminals 24, which are terminals of the circuit substrate 20, and each of the second terminal electrodes 12. Therefore, when the composite electronic component 1 is mounted on the circuit substrate 20, it is possible to equalize the connection conditions between the second terminal electrodes 12 and the terminals of the circuit substrate 20, enabling to prevent a variation in the connection. As a result, it is possible to reliably mount the composite electronic component 1 on the circuit substrate 20 and to prevent reduction in the reliability.

In the first embodiment, the insulating member 5 is in contact with the electronic components 2. In this way, the insulating member 5 supports the electronic components 2 while isolating the electronic components 2 from one another. Furthermore, the insulating member 5 is fixed to the support 4 via the conductor layer 3. Therefore, the electronic components 2 are mounted on the support 4 not only by the conductor layer 3 but also by the insulating member 5, so that the electronic components 2 can firmly be supported by the support 4. As a result, the vibration-proof performance of the composite electronic component 1 can be enhanced. The insulating member 5 is provided on the support 4 by, for example, after the electronic components 2 are mounted on the support 4 by the conductor layer 3, filling the peripheries of the electronic components 2 with an insulating resin and curing the resin.

With the above structure, in the composite electronic component 1, the second terminal electrodes 12 are exposed from the surface of the insulating member 5 located opposite the support 4. The second terminal electrodes 12 are electrically isolated from one another. When the composite electronic component 1 is mounted on the circuit substrate, the exposed portions of the second terminal electrodes 12 serve as mounting terminal electrodes to be connected to the terminals of the circuit substrate 20. The portions of the second terminal electrodes 12 that cover the short-side surfaces 10T of the element bodies 10 are electrically connected to the first substrate terminals 23 and the second substrate terminals 24 that are the terminals of the circuit substrate 20. The conductor layer 3 of the composite electronic component 1 is electrically connected to the terminals of the circuit substrate 20 not by a direct connection but by an indirect connection via the first terminal electrode 11 and the second terminal electrode 12 of the electronic components 2. In the first embodiment, the composite electronic component 1 includes the same number of mounting terminal electrodes, i.e., the second terminal electrodes 12, as the electronic components 2 included therein.

In the composite electronic component 1, the electronic components 2 are arranged in a first direction (the X direction in FIG. 1) and in a second direction (the Y direction in FIG. 2) orthogonal to the first direction. In this way, the electronic components 2 are arranged in a matrix manner. In the first embodiment, the adjacent electronic components 2 are arranged with equal spaces. However, the spaces between the adjacent electronic components 2 may be unequal. The second terminal electrodes 12 have an approximately square shape in a plan view. Therefore, by arranging the electronic components 2 in a matrix manner, it is possible to maximize the density of the electronic components 2 when surface area of the support 4 is the same. Therefore, by arranging the electronic components 2 in a matrix manner, it is possible to increase the capacitance of the composite electronic component 1. Furthermore, because the density of the electronic components 2 to be arranged can be increased by arranging the electronic components 2 in a matrix manner, it is possible to reduce the size of the composite electronic component 1.

In a structure 100 of mounting the composite electronic component (hereinafter, referred to as the mounting structure if needed) illustrated in FIG. 5, the second terminal electrodes 12 of the composite electronic component 1 are electrically connected to the first substrate terminals 23 and the second substrate terminals 24, which are the terminals of the circuit substrate 20, by solders 25. The circuit substrate 20 includes a first wiring 21 and a second wiring 22. The first substrate terminals 23 are electrically connected to the first wiring 21 and the second substrate terminals 24 are electrically connected to the second wiring 22. In the first embodiment, the composite electronic component 1 functions as a capacitor. In this case, the composite electronic component 1 is used as a decoupling capacitor or the like, which is used to supply an electric current and which is mounted near a central processing unit (CPU), in order to suppress voltage variation due to instantaneous power outage or the like.

Among the electronic components 2 whose first terminal electrodes 11 are electrically connected to one another by the conductor layer 3, the second terminal electrodes 12 of two of the electronic components 2 are connected to the first substrate terminal 23 and the second substrate terminal 24, respectively. In this way, two of the electronic components 2 serve as one electronic component pair 2P, and are connected between the first wiring 21 and the second wiring 22 via the first substrate terminal 23 and the second substrate terminal 24. In the composite electronic component 1, a plurality of the electronic component pairs 2P are connected between the first wiring 21 and the second wiring 22, and functions as, for example, a decoupling capacitor as described above.

In each of the electronic component pairs 2P, two electronic components 2 are connected in series. In the mounting structure 100, a plurality of the electronic component pairs 2P are connected to one another in parallel to the first wiring 21 and the second wiring 22. Therefore, when the composite electronic component 1 includes n (n is an even number) electronic components 2 and the capacitance of each of the electronic components 2 is Ci, the capacitance Ca of the composite electronic component 1 that functions as the capacitor becomes (n/2)×(Ci/2) in the mounting structure 100. In the first embodiment, the composite electronic component 1 includes 16 electronic components 2. Therefore, the capacitance Ca of the composite electronic component 1 becomes 4×Ci.

As in the mounting structure 100, the composite electronic component 1 can be used by connecting the electronic component pairs 2P, each including two electronic components 2 connected in series, in parallel to each other. Therefore, in the composite electronic component 1, even when a defect occurs in any of the electronic components 2, if the electronic components 2 in the electronic component pairs 2P other than the electronic component pair 2P including the defected electronic component 2 are normal, it is possible to maintain the function of the composite electronic component 1, that is, the function as the capacitor, although the capacitance is reduced. For example, in the example in FIG. 5, even when a defect occurs in one of the two electronic components 2 connected to the first wiring 21, the other one of the electronic components 2 connected to the first wiring 21 and the other two electronic components 2 connected to the second wiring 22 are electrically connected to one another by the conductor layer 3. Therefore, the composite electronic component 1 can maintain the function as the capacitor although the capacitance is reduced from Ci before the defect to 2×Ci/3.

In the composite electronic component 1, the first terminal electrodes 11 of the electronic components 2 are electrically connected to one another by the conductor layer 3. Therefore, if at least one of the electronic components 2 connected to the first wiring 21 and at least one of the electronic components 2 connected to the second wiring 22 are normal, the composite electronic component 1 can maintain the function as the capacitor although the capacitance is reduced. For example, in the example illustrated in FIG. 5, even when a defect occurs in one of the two electronic components 2 connected to the first wiring 21 and in one of the two electronic components 2 connected to the second wiring 22, the other electronic components 2 connected to the first wiring 21 and the second wiring 22 are electrically connected to each other via the conductor layer 3. Therefore, the composite electronic component 1 can maintain the function as the capacitor although the capacitance is reduced from Ci before the defect to Ci/2.

Incidentally, it may be possible to electrically connect the first terminal electrodes 11 of the odd number of, for example, three electronic components 2 to one another via the conductor layer 3, connect the second terminal electrode 12 of one of the electronic components 2 to the first wiring 21, and connect the second terminal electrodes 12 of the other two of the electronic components 2 to the second wiring 22. With this configuration, the two electronic components 2, which are connected parallel to each other, and the one electronic component 2 are connected in series between the first wiring 21 and the second wiring 22. In this case, even when a defect occurs in one of the two electronic components 2 connected parallel to each other, two electronic components 2 are still connected in series between the first wiring 21 and the second wiring 22. Therefore, the composite electronic component 1 can maintain the function as the capacitor although the capacitance is reduced from 2×Ci/3 before the defect to Ci/2.

In this way, the reliability of the composite electronic component 1 can be improved, so that the reliability of an electronic device including the composite electronic component 1 can be improved. Furthermore, in the composite electronic component 1, the electronic components 2 are integrated into one assembly. Therefore, when the electronic components 2 are the capacitor elements, it is possible to realize a large capacitance with compact dimensions. Moreover, if some of the second terminal electrodes 12 in the composite electronic component 1 are selected and connected to the first substrate terminals 23 and the second substrate terminals 24 of the circuit substrate 20, it is possible to adjust the capacitance of the composite electronic component 1 to a desired size.

If the electronic components 2 of the composite electronic component 1 include respective dielectrics, and when the electronic components 2 are mounted on the circuit substrate 20, noise may occur due to electrostriction that occurs on the dielectrics or crack may occur on the element bodies 10. The first terminal electrodes 11 of the electronic components 2 of the composite electronic component 1 are mounted on the support 4, but the second terminal electrodes 12 are free from the support 4. Therefore, in the composite electronic component 1 mounted on the circuit substrate 20, a force transmitted from the electronic components 2 to the circuit substrate 20 is released and oscillation transmitted from the electronic component to the circuit substrate 20 is reduced. As a result, the composite electronic component 1 can prevent a noise due to electrostriction that occurs on the electronic components 2 including the dielectric or can prevent occurrence of crack on the element bodies 10. When the composite electronic component 1 is mounted on the circuit substrate 20, only the second terminal electrodes 12 of the electronic components 2 are constrained by the circuit substrate 20. Therefore, the electronic components 2 of the composite electronic component 1 are less influenced by a deformation of the circuit substrate 20 compared with a case that both of the first terminal electrodes 11 and the second terminal electrodes 12 of the electronic components 2 are connected to and constrained by the circuit substrate 20. Consequently, the composite electronic component 1 can reduce a force applied to the electronic components 2 from the circuit substrate 20 due to a difference between a coefficient of thermal expansion of the composite electronic component 1 or the electronic components 2 and a coefficient of thermal expansion of the circuit substrate 20. As a result, it is possible to prevent occurrence of crack on the electronic components 2.

### First Modification

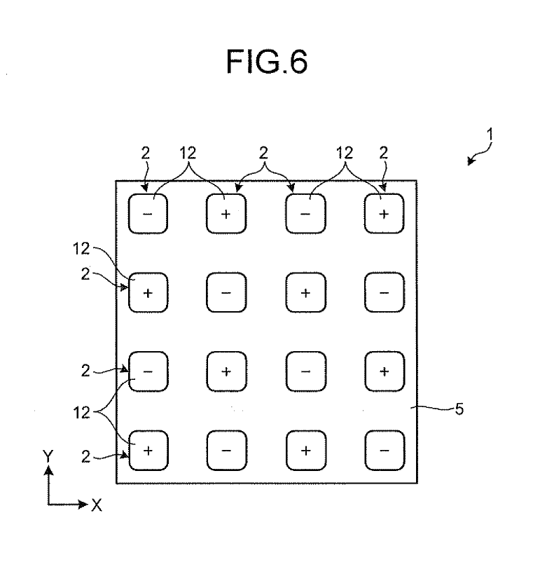

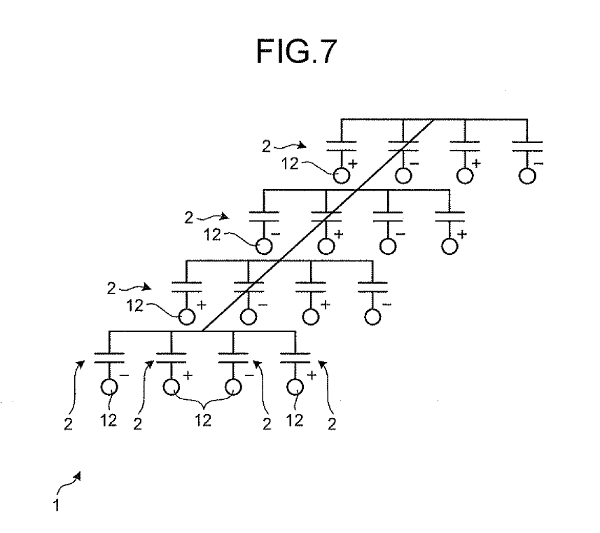

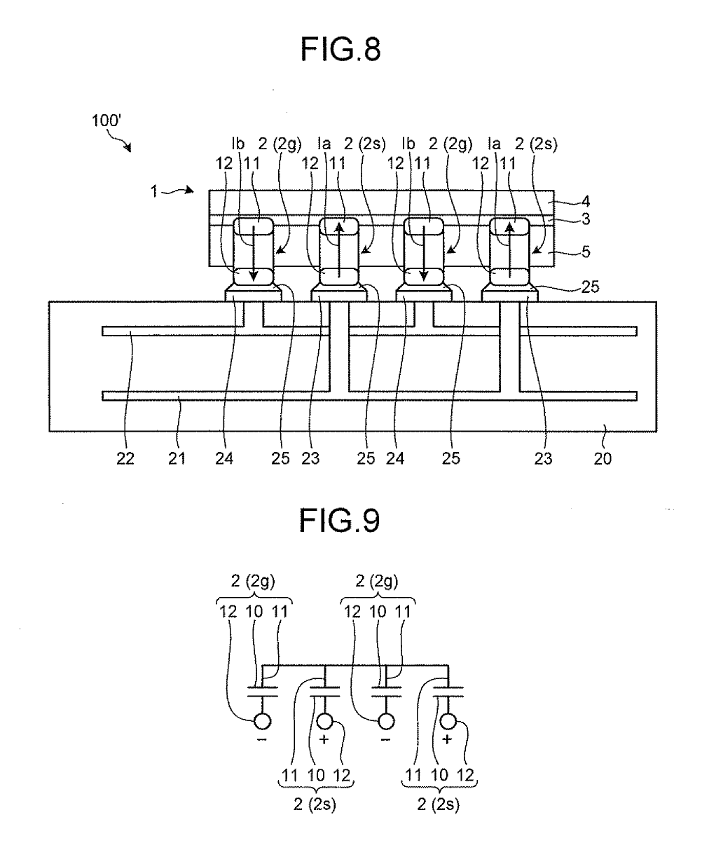

FIG. 6 and FIG. 7 are diagrams for explaining the polarities of the mounting terminal electrodes of the composite electronic component in a mounting structure according to a first modification of the first embodiment. FIG. 8 is a diagram illustrating the mounting structure according to the first modification of the first embodiment. FIG. 9 is a diagram illustrating an equivalent circuit in the mounting structure according to the first modification of the first embodiment. Signs + and − in FIG. 6, FIG. 7, and FIG. 9 indicate the polarities of the second terminal electrodes 12 serving as the mounting terminal electrodes of the electronic components 2 of the composite electronic component 1. The + sign indicates the positive electrode and the sign − indicates the negative electrode. In a mounting structure 100′ according to the first modification, the adjacent electronic components 2 of the composite electronic component 1 are connected to the first substrate terminals 23 and the second substrate terminals 24, which are the terminals of the circuit substrate 20, such that the polarities of the respective second terminal electrodes 12 become opposite to each other. In the first modification, the electronic components 2 are capacitor elements.

Therefore, as illustrated in FIG. 6 and FIG. 7, the positive electrodes and the negative electrodes of the second terminal electrodes 12 arranged in a grid-like manner form a staggered pattern. Specifically, the positive electrodes and the negative electrodes of the second terminal electrodes 12 of the electronic components 2 arranged in a matrix manner are alternately arranged in the row direction and in the column direction. In the mounting structure 100 illustrated in FIG. 8, the first wiring 21 of the circuit substrate 20 is a signal line or a power supply line of the circuit substrate 20, and the second wiring 22 is a GND line of the circuit substrate 20. The second terminal electrodes 12 of the electronic components 2 denoted by symbols 2s are connected to the first wiring 21 serving as the positive electrode via the solders 25 and the first substrate terminals 23. The second terminal electrodes 12 of the electronic components 2 denoted by symbols 2g are connected to the second wiring 22 serving as the negative electrode via the solders 25 and the second substrate terminals 24.

As illustrated in FIG. 8, the first terminal electrodes 11 of the adjacent electronic components 2s and 2g are connected to each other via the conductor layer 3. The second terminal electrodes 12 of the electronic components 2s are connected to the first wiring 21 of the circuit substrate 20, and the second terminal electrodes 12 of the electronic components 2g are connected to the second wiring 22 of the circuit substrate 20. When electric currents flow from the first wiring 21 to the second wiring 22, electric currents flowing through the electronic components 2s are denoted by Ia and electric currents flowing through the electronic components 2g are denoted by Ib. The electric currents Ia flow from the second terminal electrodes 12 to the first terminal electrodes 11 of the electronic components 2s. The electric currents Ib flow from the first terminal electrodes 11 to the second terminal electrodes 12 of the electronic components 2g. In this way, in the mounting structure 100′, the directions of the electric currents Ia and Ib that flow through the adjacent electronic components 2s and 2g of the composite electronic component 1 are opposite to each other. As a result, the composite electronic component 1 and the mounting structure 100′ can reduce the ESL.

If a distance between the adjacent electronic components 2s and 2g is reduced, it becomes possible to further reduce the ESL. To reduce the distance between the adjacent electronic components 2s and 2g, it is preferable to reduce the dimensions of the electronic components 2s and 2g. To reduce the ESL, as in the first modification, it is preferable to arrange the positive electrodes and the negative electrodes of the second terminal electrodes 12 in a staggered manner. Incidentally, the second terminal electrodes 12 of the electronic components 2 arranged in a matrix manner may be arranged such that the polarities thereof become opposite for each row or for each column. Even with this configuration, the polarity of a certain electronic component 2 and the polarity of the electronic component 2 adjacent to this electronic component 2 in the row direction or in the column direction become opposite to each other. Therefore, it is possible to reduce the ESL. Namely, in the mounting structure 100′ of the first modification, it is sufficient to mount the composite electronic component 1 on the circuit substrate 20 such that the polarity of each of the electronic components 2 and the polarity of at least one of the electronic components 2 adjacent to each of the electronic components 2 become opposite to each other. With this configuration, it is possible to reduce the ESL of the composite electronic component 1.

### Second Modification

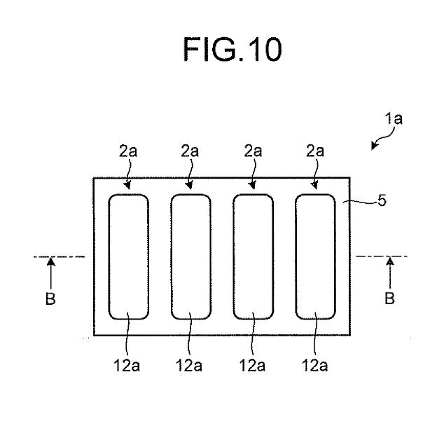

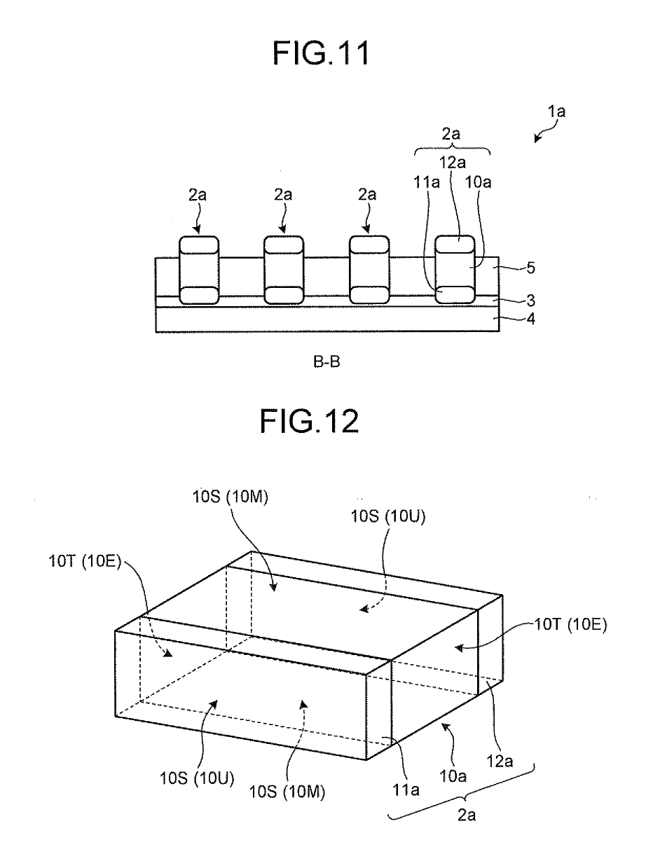

FIG. 10 is a plan view of a composite electronic component according to a second modification of the first embodiment. FIG. 11 is a diagram viewed in the direction of arrow B-B in FIG. 10. FIG. 12 is a perspective view of an electronic component included in the composite electronic component according to the second modification of the first embodiment. A composite electronic component 1a includes a plurality of electronic components 2a (four in the second modification). First terminal electrodes 11a of the electronic components 2a are electrically connected to one another by the conductor layer 3. At least parts of second terminal electrodes 12a are exposed from the surface of the insulating member 5 and serve as mounting terminal electrodes.

In the second modification, each of the electronic components 2a of the composite electronic component 1a is formed such that the first terminal electrode 11a and the second terminal electrode 12a are formed on the respective opposing long-side surfaces 10S where the inner electrode is exposed among the four long-side surfaces 10S connecting the two opposing short-side surfaces 10T, 10T (the first and second end surfaces 10E, 10E) of an element body 10a having a cuboid shape. The long-side surfaces 10S, 10S correspond to the first and second side surfaces 10U, 10U, rather than the first and second principal surfaces 10M, 10M. The first terminal electrode 11a and the second terminal electrode 12a cover the whole of the long-side surfaces 10S on which they are formed. The first terminal electrode 11a and the second terminal electrode 12a extend to parts of the two long-side surfaces 10S and parts of the short-side surfaces 10T that are not entirely covered by the first terminal electrode 11a and the second terminal electrode 12a.

In the second modification, the electronic components 2a are capacitor elements. Each of the capacitor elements is a laminated element, in which at least two inner electrodes and a dielectric are laminated such that one of the inner electrodes sandwiching the dielectric is electrically connected to the first terminal electrode 11a and the other one of the inner electrodes is electrically connected to the second terminal electrode 12a. The long-side surfaces 10S of the element body 10a of the electronic component 2a have an approximately rectangular shape in a plan view. The short-side surfaces 10T of the element body 10a have an approximately rectangular shape or a square shape in a plan view. When the short-side surfaces 10T have the approximately rectangular shape, the long sides of the short-side surfaces 10T are shorter than the long sides of the long-side surfaces 10S. In the second modification, the short sides of the long-side surfaces 10S that are entirely covered by the first terminal electrode 11a and the second terminal electrode 12a are shorter than the short sides of the long-side surfaces 10S on parts of which the first terminal electrode 11a and the second terminal electrode 12a extend.

In the electronic component 2a structured as above, the widths of the inner electrodes provided inside the element body 10a are large and the lengths of the inner electrodes are small. Therefore, it is possible to reduce current pathway. As a result, the electronic component 2a can reduce the ESL. In this example, the widths of the inner electrodes are dimensions in the longitudinal direction of the long-side surfaces 10S that are entirely covered by the first terminal electrode lie and the second terminal electrode 12a, that is, the widths of the inner electrodes output to the first and second side surfaces. The lengths of the inner electrodes are dimensions in a direction from the first terminal electrode 11a to the second terminal electrode 12a.

The composite electronic component 1a including the above-described electronic components 2a can ensure the reliability, reduce noise, and efficiently reduce the ESL. When the composite electronic component 1a is mounted on a circuit substrate, and if the adjacent second terminal electrodes 12a are arranged such that the respective polarities thereof become opposite to each other, it becomes possible to efficiently reduce the ESL as described above.

### Third Modification

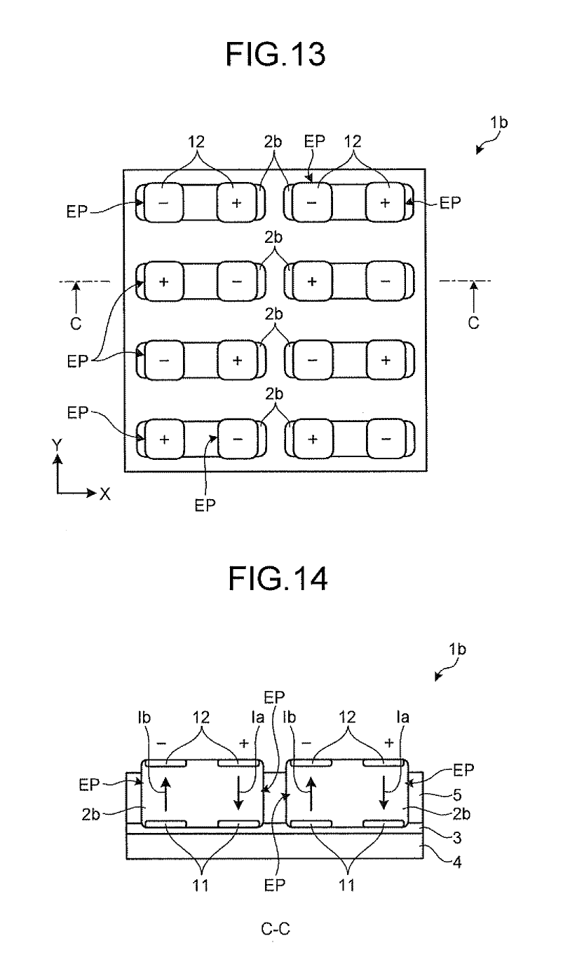

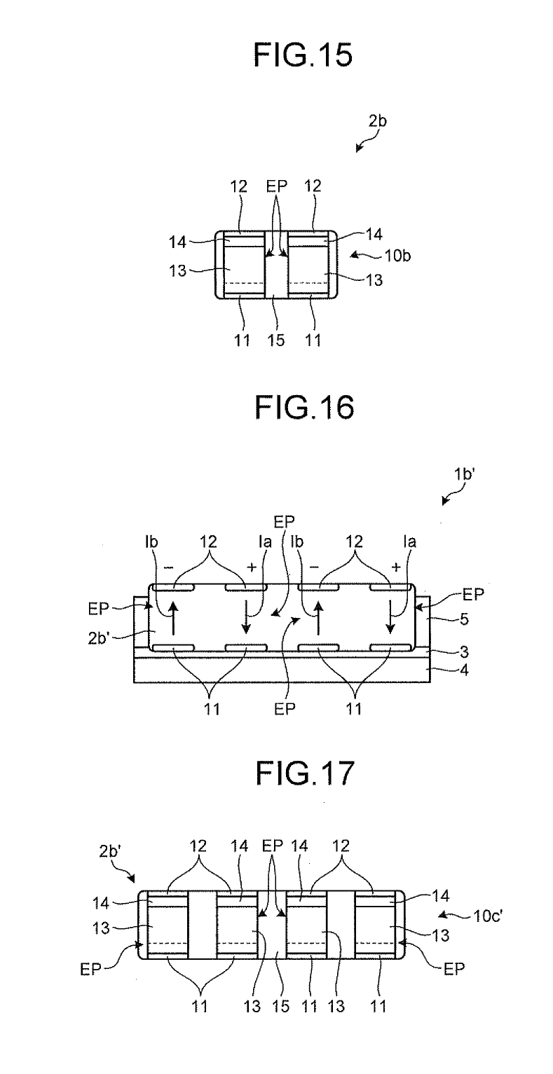

FIG. 13 is a plan view of a composite electronic component according to a third modification of the first embodiment. FIG. 14 is a diagram viewed in the direction of arrow C-C in FIG. 13. FIG. 15 is a cross-sectional view illustrating an example of an electronic component included in the composite electronic component according to the third modification of the first embodiment. In the third modification, electronic components each including a plurality of element portions are used as electronic components 2b of a composite electronic component 1b. As illustrated in FIG. 13, the composite electronic component 1b includes a plurality of the electronic components 2b (eight in the third modification). As illustrated in FIG. 14, the first terminal electrodes 11 of the electronic components 2b are electrically connected to one another by the conductor layer 3. At least parts of the second terminal electrodes 12 are exposed from the insulating member 5 and serve as mounting terminal electrodes.

Each of the electronic components 2b includes a plurality of element portions EP (two in the third modification). In the third modification, the element portions EP are capacitors. Namely, the electronic components 2b are capacitor arrays. As illustrated in FIG. 15, each of the element portions EP of the electronic components 2b includes an element body 10b, in which a plurality of inner electrodes 13 and 14 and the dielectric 15 are laminated such that the inner electrode 13 is electrically connected to the first terminal electrode 11 and the inner electrode 14 is electrically connected to the second terminal electrode 12 with the dielectric 15 sandwiched. Each of the electronic components 2b includes two first terminal electrodes 11 and two second terminal electrodes 12 for the respective element portions EP. The two first terminal electrodes 11 are arranged on one long-side surface of the electronic component 2b and the two second terminal electrodes 12 are arranged on the other long-side surface opposing the long-side surface where the first terminal electrodes 11 are arranged.

As illustrated in FIG. 13, in the composite electronic component 1b, two electronic components 2b are arranged in a direction in which the element portions EP of the electronic components 2b are arranged, and four electronic components 2b are arranged in a direction orthogonal to the direction in which the element portions EP are arranged. With this structure, in the composite electronic component 1b, four element portions EP are arranged in each of a first direction (the X direction in FIG. 13) and in a second direction (the Y direction in FIG. 13). That is, a plurality of the element portions EP are arranged in a matrix manner.

As illustrated in FIG. 14, the composite electronic component 1b can be mounted on a circuit substrate such that the polarities of the two adjacent element portions EP in one electronic component 2b becomes opposite to each other. In this example, the second terminal electrode 12 indicated by + is used as a positive electrode and connected to a signal line or a power supply line of the circuit substrate, and the second terminal electrode 12 indicated by − is used as a negative electrode and connected to a GND line of the circuit substrate. In the element portion EP including the second terminal electrode 12 indicated by +, the electric current Ia flows from the second terminal electrode 12 to the first terminal electrode 11. In the element portion EP including the second terminal electrode 12 indicated by −, the electric current Ib flows from the first terminal electrode 11 to the second terminal electrode 12. By mounting the composite electronic component 1b on the circuit substrate in the above-described manner, the directions of the electric currents Ia and 1b that flow through the adjacent element portions EP and EP of the electronic component 2b become opposite to each other. As a result, the composite electronic component 1b can reduce the ESL.

FIG. 16 is a partial cross-sectional view illustrating an example in which a different electronic component is applied to the composite electronic component according to the third modification of the embodiment. FIG. 17 is a cross-sectional view of the electronic component illustrated in FIG. 16. A composite electronic component 1b′ includes a plurality of electronic components 2b′, each including four element portions EP. FIG. 16 illustrates only one of the electronic components 2b′ included in the composite electronic component 1b′; however, in this example, the composite electronic component 1b′ includes four electronic components 2b′.

As illustrated in FIG. 17, each of the electronic components 2b′ includes the four element portions EP. In this example, the element portions EP are capacitors. Therefore, the electronic components 2b′ are capacitor arrays. The structures of the element portions EP included in the electronic components 2b′ are the same as those of the element portions EP included in the electronic components 2b. As illustrated in FIG. 16, similarly to the composite electronic component 1b, the composite electronic component 1b′ can be mounted on a circuit substrate such that the polarities of two adjacent element portions EP in one electronic component 2b′ become opposite to each other. Therefore, similarly to the composite electronic component 1b, the composite electronic component 1b′ can set the directions of the electric currents Ia and Ib that flow through the adjacent element portions EP, EP to be opposite to each other. As a result, it is possible to reduce the ESL.

The composite electronic components 1b and 1b′ include the electronic components 2b and 2b′ as array electronic components, respectively. Therefore, compared with the composite electronic components 1 and 1a respectively using the electronic components 2 and 2a each including only one element portion, it becomes possible to reduce the number of the electronic components 2b and 2b′. As a result, the composite electronic components 1b and 1b′ can reduce the number of mountings of the electronic components 2b on the support 4 by a mounting device, such as a mounter. Therefore, it is possible to reduce a time taken to mount the electronic components 2b and 2b′ on the support 4. Furthermore, because the composite electronic components 1b and 1b′ include the array electronic components, it becomes possible to more easily handle the electronic components 2b and 2b′ compared with the electronic components 2 and 2a each including only one element portion. Therefore, the composite electronic component 1b and 1b′ can improve the operating efficiency in mounting the electronic components 2b on the support 4 by a mounting device, such as a mounter. In this way, the composite electronic component 1b and 1b′ can improve the operating efficiency in mounting the electronic components 2b and 2b′ on the support 4, so that the productivity can be improved. The above advantageous effects are enhanced as the number of the element portions EP included in the array electronic component increases. Therefore, the composite electronic component 1b′ using the electronic components 2b′ each including four element portions EP can more improve the operating efficiency and the productivity than the composite electronic component 1b using the electronic components 2b each including two element portions EP.

### Fourth Modification

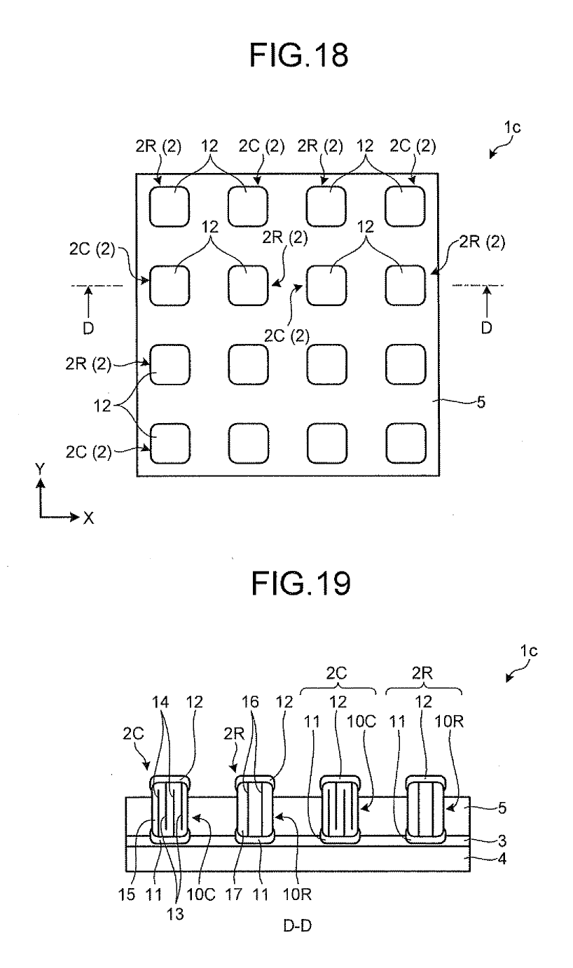

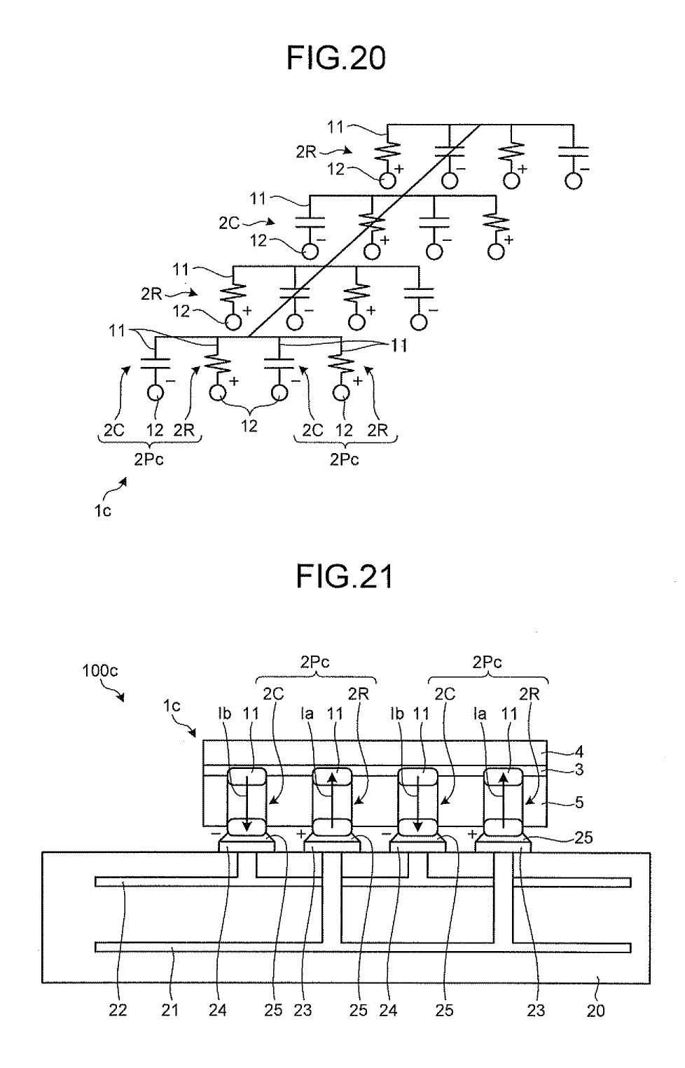

FIG. 18 is a plan view of a composite electronic component according to a fourth modification of the first embodiment. FIG. 19 is a diagram viewed in the direction of arrow D-D in FIG. 18. FIG. 20 is a diagram illustrating an equivalent circuit of the composite electronic component according to the fourth modification of the first embodiment. FIG. 21 is a diagram illustrating amounting structure according to the fourth modification of the first embodiment. A composite electronic component 1c according to the fourth modification includes two types of electronic components 2C and 2R having different functions. In the fourth modification, the electronic components 2C are capacitor elements and the electronic components 2R are resistor elements (for example, chip resistors); however, this is not limited thereto.

The electronic components 2C and the electronic components 2R are arranged so as to be adjacent to each other on the surface of the support 4. Therefore, the electronic components 20 and the electronic components 2R are arranged in a staggered manner. Namely, in the composite electronic component 1c, the electronic components 2C and the electronic components 2R are alternately arranged in a first direction (the X direction in FIG. 18) and in a second direction (the Y direction in FIG. 18). In this way, in the composite electronic component 1c, the electronic components 2C and 2R are alternately arranged in a matrix manner.

Each of the electronic components 2C as the capacitor elements includes, as illustrated in FIG. 19, an element body 10C, in which a plurality of the inner electrodes 13 and 14 and the dielectric 15 are laminated such that the inner electrodes 13 are electrically connected to the first terminal electrode 11 and the inner electrodes 14 are electrically connected to the second terminal electrode 12 with the dielectric 15 sandwiched. Each of the electronic components 2R as the resistor elements includes an element body 10R, in which resistors 16 and dielectrics 17 are laminated such that the resistor 16 are electrically connected to the first terminal electrode 11 and the second terminal electrode 12. For example, a ferrite bead may be used as the resistors 16.

As illustrated in FIG. 21, in a mounting structure 100c of the composite electronic component 1c, the adjacent electronic components 2C and 2R are connected in series to form an electronic component pair 22c, and the electronic component pairs 2Pc are arranged parallel to each other between the first wiring 21 and the second wiring 22 of the circuit substrate 20. In this way, by connecting the adjacent electronic components 2C and 2R in series, the composite electronic component 1c can increase an equivalent series resistance (ESR). In the composite electronic component 1c, if the ESR is too low, noise may be increased due to resonance. Therefore, in the fourth modification, the resistor element (the electronic component 2R) is connected to the capacitor element (the electronic component 2C) in series in order to prevent resonance of the composite electronic component 1c. The ferrite bead applicable to the resistors 16 of the electronic component 2R serving as the resistor element has a property of increasing the electric resistance at a higher high frequency. Therefore, if the ferrite bead is used as the resistors 16 of the electronic component 2R, it is possible to increase the ESR of the composite electronic component 1c with respect to a high-frequency signal.

Furthermore, in the fourth modification, the adjacent electronic components 2C and 2R included in the electronic component pair 2Pc are connected in series. The second terminal electrode 12 of the electronic component 2R serving as the resistor element is used as a positive electrode and connected to the first wiring 21 via the first substrate terminal 23 of the circuit substrate 20, and the second terminal electrode 12 of the electronic component 2C serving as the capacitor element is used as a negative electrode and connected to the second wiring 22 via the second substrate terminal 24 of the circuit substrate 20. The first wiring 21 is, for example, a signal line or a power supply line of the circuit substrate 20, and the second wiring 22 is, for example, a GND line of the circuit substrate 20.

In the electronic components 2R including the second terminal electrodes 12 serving as the positive electrodes, the electric currents 1a flow from the second terminal electrodes 12 to the first terminal electrodes 11. In the electronic components 2C including the second terminal electrodes 12 serving as the negative electrodes, the electric currents Ib flow from the first terminal electrodes 11 to the second terminal electrodes 12. In the mounting structure 100c, the composite electronic component 1c is mounted on the circuit substrate 20 in the above-described manner, so that the directions of the electric currents Ia and Ib that flow through the electronic components 2R and 2C become opposite to each other. As a result, the composite electronic component 1c can reduce the ESL.

As described above, according to the first embodiment and the modifications, the first terminal electrodes of a plurality of the electronic components are electrically connected to one another via the conductor layer and the second terminal electrodes are used as the mounting terminal electrodes connected to the terminals of the circuit substrate. With this configuration, according to the first embodiment and the modifications, even when a defect occurs in an electronic component included in the composite electronic component, if an electronic component of any of the electronic component pairs other than an electronic component pair including the defected electronic component is normal, it is possible to maintain the function as the capacitor. Therefore, according to the first embodiment and the modifications, it is possible to improve the reliability of the composite electronic component including a plurality of the electronic components, enabling to improve the reliability of an electronic device including the composite electronic component. The configurations according to the above embodiment or modifications may be applied appropriately to embodiments described below. The embodiments including the configurations of the above embodiment or modifications can achieve the same advantageous effects of the above embodiment or the modifications.

### Second Embodiment

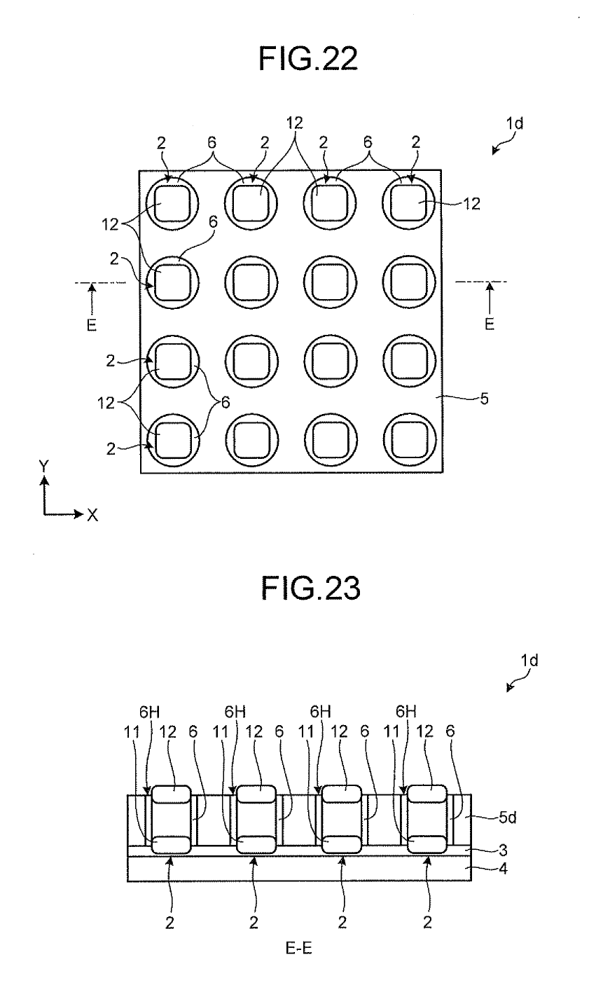

FIG. 22 is a plan view of a composite electronic component according to a second embodiment. FIG. 23 is a diagram viewed in the direction of arrow E-E in FIG. 22. A composite electronic component 1d according to the second embodiment includes through holes 6 that penetrate through an insulating member 5d from the side where the second terminal electrodes 12 of the electronic components 2 are exposed to the support 4. The electronic components 2 are arranged inside the through holes 6. The other configurations are the same as those of the composite electronic component 1 of the first embodiment.

The insulating member 5d includes a plurality of the through holes 6 that penetrate through the greatest two surfaces. The number of the through holes 6 is the same as the number of the electronic components 2 of the composite electronic component 1d. The electronic components 2 are arranged inside the through holes 6. The first terminal electrodes 11 of the electronic components 2 are electrically connected to the conductor layer 3, and at least parts of the second terminal electrodes 12 are exposed from openings 6H of the through holes 6. In the second embodiment, the second terminal electrodes 12 are exposed from the openings 6H of the through holes 6 so as to protrude from the openings 6H of the through holes 6.

The composite electronic component 1d is manufactured such that a conductive adhesive member to be the conductor layer 3 is coated on the support 4 and the insulating member 5d having the through holes 6 is placed on the conductive adhesive member. Thereafter, the electronic components 2 are inserted into the through holes 6 from the first terminal electrodes 11 side such that the first terminal electrodes 11 and the conductive adhesive member come into contact with each other, so that the electronic components 2 are mounted on the support 4. Subsequently, the conductive adhesive member is cured to electrically connect the first terminal electrodes 11 to one another and to bond the support 4 and the insulating member 5d. In this way, the composite electronic component 1d is completed. In the composite electronic component 1d, when the electronic components 2 are mounted on the support 4, the through holes 6 function to guide the electronic components 2. Therefore, the operation of mounting the electronic components 2 on the support 4 can be made easy. The through holes 6 also function as a guide to determine the positions of the electronic components 2. Therefore, it is possible to improve the positional accuracy of the electronic components 2 of the composite electronic component 1d. Furthermore, in the composite electronic component 1d, the insulating member 5d having a plate-like shape is mounted on the support 4. Therefore, compared with the composite electronic component 1 according to the first embodiment, in which the insulating member 5 is formed with a filled insulating resin, it becomes possible to improve the dimensional accuracy of the thickness of the insulating member 5d (a dimension in a direction orthogonal to the greatest two surfaces) and the degree of flatness of the surface on the second terminal electrodes 12 side. As a result, it is possible to prevent the second terminal electrodes 12 from being buried in the insulating member 5d.

As described above, according to the second embodiment, in addition to the same advantageous effects of the first embodiment, it is possible to improve the operating efficiency in mounting the electronic components on the support, and it is possible to improve the positional accuracy of a plurality of the electronic components. The configurations of the above embodiments or modifications may be applied appropriately to embodiments described below. The embodiments including the configurations of the above embodiments or modifications can achieve the same advantageous effects of the above embodiments or modifications.

### Third Embodiment

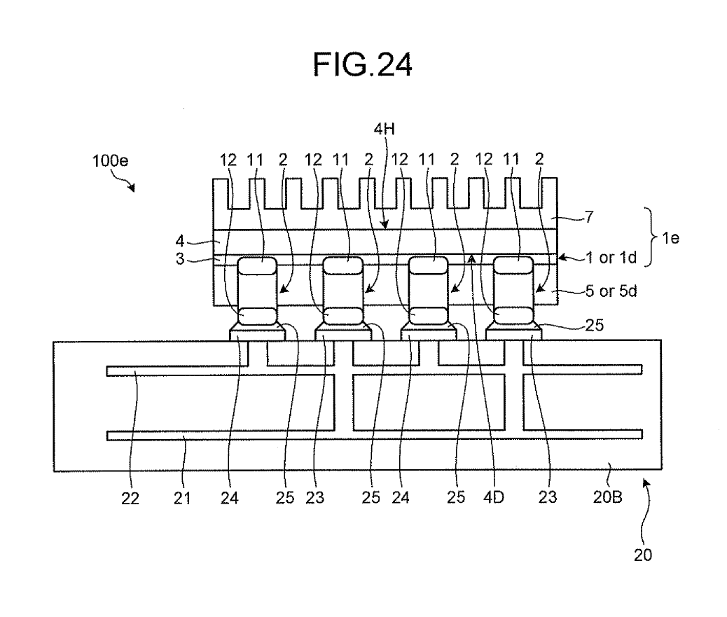

FIG. 24 is a diagram illustrating a composite electronic component and a mounting structure according to a third embodiment. A composite electronic component 1e according to the third embodiment includes a radiator member 7 on one side of the support 4 opposite the side where the electronic components 2 are arranged. The other configurations are the same as those of the composite electronic component 1 of the first embodiment or the composite electronic component 1d of the second embodiment. The radiator member 7 releases heat generated by the electronic components 2 of the composite electronic component 1e into the atmosphere to prevent an increase in the temperature of the composite electronic component 1e. In a mounting structure 100e, the composite electronic component 1e is mounted on the circuit substrate 20 by joining the second terminal electrodes 12 of the composite electronic component 1e including the radiator member 7 to the first substrate terminals 23 and the second substrate terminal s24 of the circuit substrate 20 by the solders 25. The composite electronic component 1e has high radiation performance, so that the composite electronic component 1e can preferably used when the circuit substrate 20 includes an electronic component whose temperature easily increases or in an environment where a temperature easily increases.

As illustrated in FIG. 24, the composite electronic component 1e is structured such that the radiator member 7 is attached to the support 4 of the composite electronic component 1 according to the first embodiment or the composite electronic component 1d according to the second embodiment. Specifically, in the composite electronic component 1e, the radiator member 7 is mounted on a surface 4H opposing a surface 4D where the conductor layer 3 is arranged, that is, on the side opposite the side where the electronic components 2 are arranged, between the two greatest surfaces 4H and 4D of the support 4 of the composite electronic component 1 or the composite electronic component 1d. The radiator member 7 is formed by using a material with high thermal conductivity. In the third embodiment, for example, a metal material, such as aluminum, aluminum alloy, copper, or copper alloy, is used for the radiator member 7; however, this is not limited thereto. The radiator member 7 includes a plurality of fins on the side opposite the support 4. The fins increase the surface area of the radiator member 7, so that the radiation performance can be improved.

In the third embodiment, the support 4, on which the electronic components 2 and the insulating member 5 or Se are mounted via the conductor layer 3, may be a conductor or an insulator. In general, a conductor is a good conductor of heat. Therefore, if a conductor is used as the support 4, it is possible to more efficiently transfer heat from the electronic components 2 of the composite electronic component 1e to the radiator member 7. If an insulator is used as the support 4, it is possible to electrically isolate the first terminal electrodes 11 and the radiator member 7. Therefore, it is possible to prevent short circuit between the electronic components 2 and a casing housing the circuit substrate 20 or between the electronic components 2 and other electronic components mounted on the circuit substrate 20 via the radiator member 7.

As described above, according to the third embodiment, in addition to the advantageous effects of the first embodiment, it is possible to improve the radiation performance of the composite electronic component. The configurations of the above embodiments or modifications may be applied appropriately to embodiments described below. The embodiments including the configurations of the above embodiments or modifications can achieve the same advantageous effects of the above embodiments or modifications.

### Fourth Embodiment

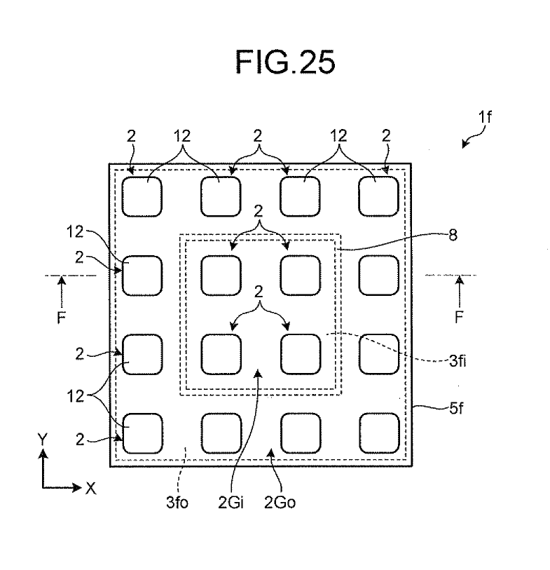

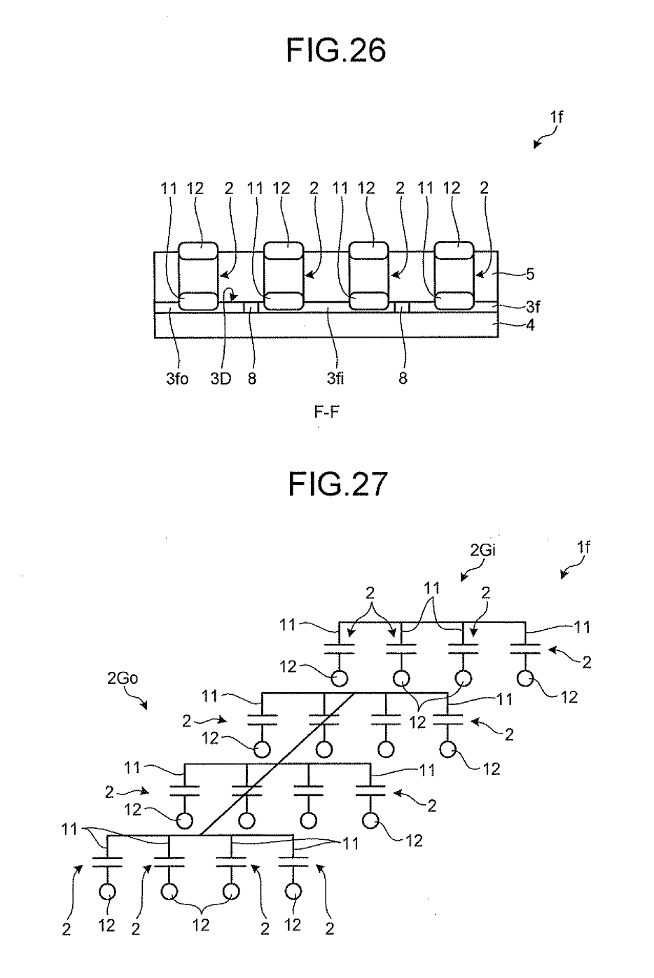

FIG. 25 is a plan view of a composite electronic component according to a fourth embodiment. FIG. 26 is a diagram viewed in the direction of arrow F-F in FIG. 24. FIG. 27 is a diagram illustrating an equivalent circuit of the composite electronic component according to the fourth embodiment. In a composite electronic component 1f of the fourth embodiment, the support 4 is an insulator and a conductor layer 3f includes a groove 8 that surrounds a plurality of the electronic components 2 adjacent to each other and that reaches the support 4. The other configurations are the same as those of the composite electronic component 1 of the first embodiment. In the fourth embodiment, the electronic components 2 are capacitors; however, this is not limited thereto.

As illustrated in FIG. 25 and FIG. 26, the composite electronic component 1f includes 16 electronic components 2, which are arranged in four rows in the X direction as a first direction and in four columns in the Y direction as a second direction orthogonal to the first direction. In this way, the composite electronic component 1f includes the 16 electronic components 2 arranged in a matrix of 4×4. If the electronic components 2 of the composite electronic component 1f are considered as elements (components) of the matrix, the electronic components 2 corresponding to the element (2, 2), (2, 3), (3, 2), and (3, 3) are surrounded by the groove 8. As illustrated in FIG. 25 and FIG. 26, the groove 8 is arranged on the conductor layer 3f and reaches the support 4. Specifically, the groove 8 penetrates through the conductor layer 3f from the second terminal electrodes 12 side to the surface of the support 4 on the first terminal electrodes 11 side. With this structure, the groove 8 divides the conductor layer 3f into two regions, that is, an inner region 3fi and an outer region 3fo, and electrically isolates the inner region 3fi and the outer region 3fo.

The conductor layer 3f in the outer region 3fo electrically connects the first terminal electrodes 11 of the twelve electronic components 2 arranged in the outer region 3fo. The conductor layer 3f in the inner region 3fi electrically connects the first terminal electrodes 11 of the four electronic components 2 arranged in the inner region 3fi. With this structure, the composite electronic component 1f includes, as in the equivalent circuit illustrated in FIG. 27, an inner electronic component group 2Gi, in which the first terminal electrodes 11 of the four electronic components 2 are electrically connected to one another, and an outer electronic component group 2Go, in which the first terminal electrodes 11 of the twelve electronic components 2 are electrically connected to one another. In the fourth embodiment, the electronic components 2 are the capacitors. Therefore, in the composite electronic component 1f, each of the inner electronic component group 2Gi and the outer electronic component group 2Go functions as one capacitor. Namely, the electronic components 2 included in the inner electronic component group 2Gi and the electronic components 2 included in the outer electronic component group 2Go serve as capacitors with a predetermined function.

In this way, the composite electronic component 1f includes a plurality of electronic component groups having a predetermined function (in the second embodiment, the function as the capacitor). Each of the electronic component groups include a plurality of the electronic components 2, and the first terminal electrodes 11 are electrically connected to one another. Therefore, the reliability of each of the electronic component groups can be improved. Consequently, the composite electronic component 1f can include a plurality of electronic component groups having high reliability. The composite electronic component 1f includes the same insulating member 5 as that of the composite electronic component 1 of the first embodiment. However, the insulating member 5 of the composite electronic component 1f is not limited to this. For example, as in the insulating member 5d of the composite electronic component 1d according to the second embodiment, it may be possible to include the through holes 6 in which the electronic components 2 are arranged.

### First Modification

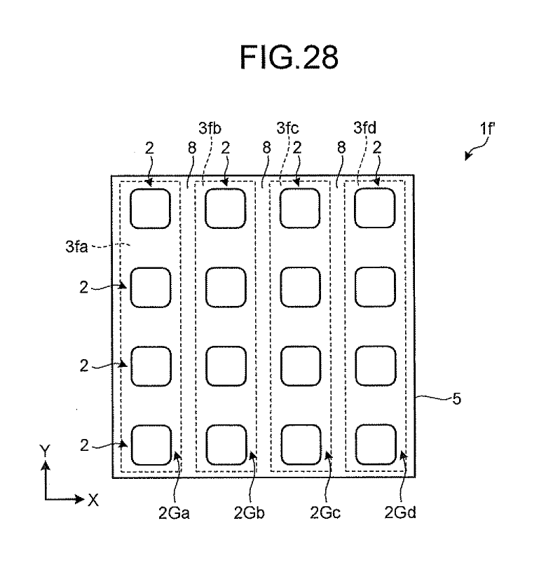

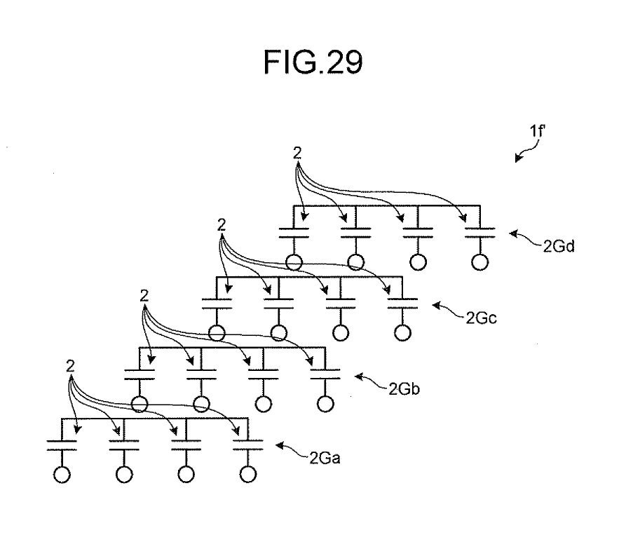

FIG. 28 is a plan view of a composite electronic component according to a first modification of the fourth embodiment. FIG. 29 is a diagram illustrating an equivalent circuit of the composite electronic component according to the first modification of the fourth embodiment. A composite electronic component 1f′ according to the first modification is the same as the composite electronic component 1f according to the fourth embodiment, but is different in that a conductor layer 3f′ is divided into regions. In the composite electronic component 1f′, three grooves 8 divide the conductor layer 3f′ into four regions, that is, a first region 3fa, a second region 3fb, a third region 3fc, and a fourth region 3fd. The first region 3fa, the second region 3fb, the third region 3fc, and the fourth region 3fd are electrically isolated from one another. In each of the first region 3fa, the second region 3fb, the third region 3fc, and the fourth region 3fd, the first terminal electrodes 11 of the four the electronic components 2 are electrically connected to one another. In this way, the three grooves 8 divide the 16 electronic components 2 arranged in a matrix of 4×4 for each row, so that four electronic component groups 2Ga, 2Gb, 2Gc, and 2Gd are formed.

In the composite electronic component 1f′, each of the four electronic component groups 2Ga, 2Gb, 2Gc, and 2Gd functions as one capacitor. Each of the electronic component groups 2Ga, 2Gb, 2Gc, and 2Gd of the composite electronic component 1f includes a plurality of the electronic components 2, and the first terminal electrodes 11 are electrically connected to one another. Therefore, the reliability of each of the electronic component groups 2Ga, 2Gb, 2Gc, and 2Gd can be improved. Consequently, the composite electronic component 1f′ can include a plurality of the electronic component groups 2Ga, 2Gb, 2Gc, and 2Gd having high reliability. As described in the fourth embodiment and the present modification, if the first terminal electrodes 11 of the electronic components 2 in each of the regions divided by the grooves 8 in the conductor layer 3f or 3f′ are electrically connected to one another, how to divide the conductor layer is not specifically limited.

### Second Modification

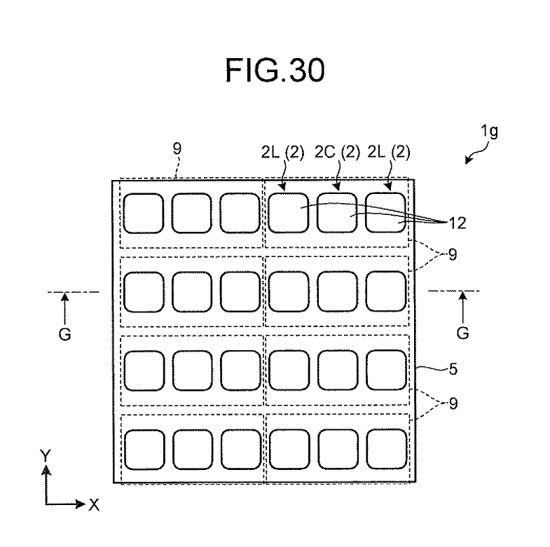

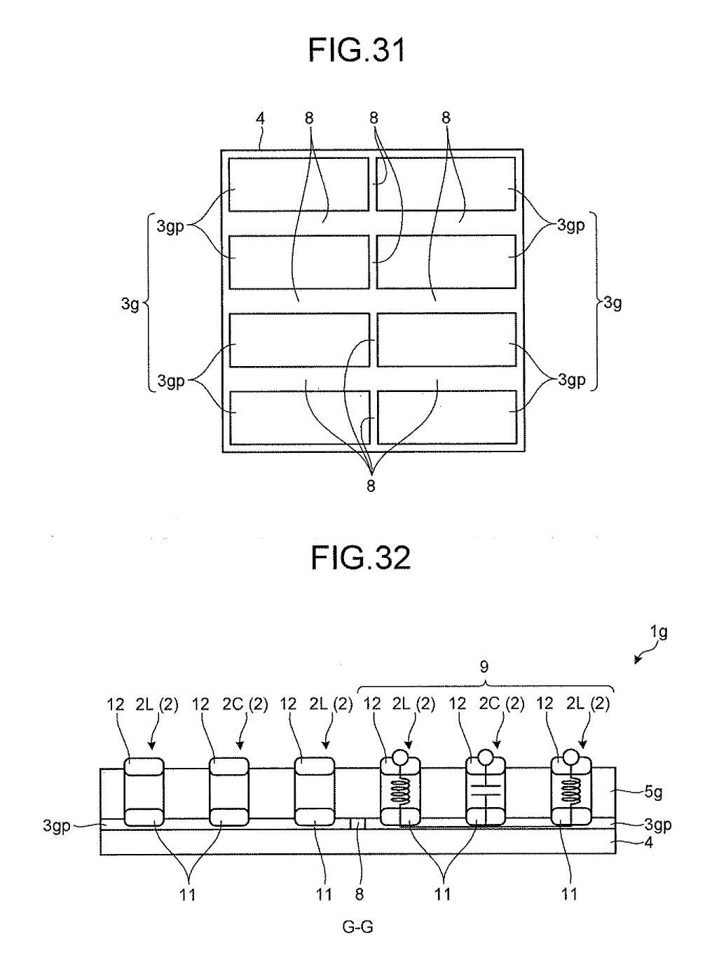

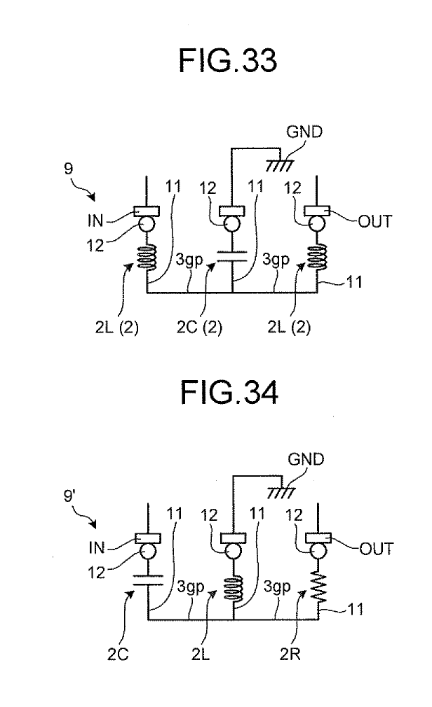

FIG. 30 is a plan view of a composite electronic component according to a second modification of the fourth embodiment. FIG. 31 is a plan view illustrating a configuration of a conductor layer included in the composite electronic component according to the second modification of the fourth embodiment. FIG. 32 is a diagram viewed in the direction of arrow G-G in FIG. 30. FIG. 33 is a diagram illustrating an equivalent circuit of the composite electronic component according to the second modification of the fourth embodiment. A composite electronic component 1g according to the second modification is the same as the composite electronic component 1f or 1f′ of the fourth embodiment or the first modification of the fourth embodiment, but is different in that the electronic components 2 arranged in each of the regions divided by the grooves have a filter function as the predetermined function.

The composite electronic component 1g includes a plurality of filters 9 (eight in the second modification). The number of the filters 9 included in the composite electronic component 1g is not specifically limited. Each of the filters 9 includes three electronic components 2. The electronic components 2C are capacitor elements, and electronic components 2L, are inductor elements (such as chip inductors). In the following, the electronic components 2C are referred to as the capacitor elements 2C and the electronic components 2L, are referred to as the inductor elements 2L if needed.

As illustrated in FIG. 31, the composite electronic component 1g includes a plurality of regions 3gp obtained by dividing a conductor layer 3g by the grooves 8. In the second modification, the conductor layer 3g is divided into the eight regions 3gp by three grooves 8 and one groove 8 orthogonal to the three grooves 8. The regions 3gp are electrically isolated from one another. As illustrated in FIG. 32, each of the regions 3gp electrically connect the first terminal electrode 11 of the one capacitor element 2C and the first terminal electrodes 11 of the two inductor elements 2L. With this structure, the filter 9 including the one capacitor element 2C and the two inductor elements 2L is formed. At least parts of the second terminal electrodes 12 of the one capacitor element 2C and the two inductor elements 2L are exposed from the surface of the insulating member 5 and serve as mounting terminal electrodes of the composite electronic component 1g. The insulating member 5 may include the through holes 6 in which the electronic components 2 are arranged, as in the insulating member 5d of the composite electronic component 1d according to the second embodiment.

As illustrated in FIG. 33, in the filter 9, the second terminal electrode 12 of one of the inductor elements 2L is electrically connected to a signal input terminal IN, and the second terminal electrode 12 of the other one of the inductor elements 2L is electrically connected to the signal output terminal OUT. The second terminal electrode 12 of the capacitor element 20 is electrically connected to the ground terminal GND. Therefore, the filter 9 functions as a low-pass filter. In this case, it may be possible to change at least one of the two inductor elements 2L to a resistor element. As the resistor element, a ferrite bead may be used. It may be possible to use ferrite beads instead of the two inductor elements 2L.

FIG. 34 is a diagram illustrating an equivalent circuit of another filter. A filter 9′ includes, as the electronic components, two capacitor elements 2C and one inductor element 2L. In the filter 9′, the second terminal electrode 12 of one of the capacitor elements 2C is connected to the signal input terminal IN, and the second terminal electrode 12 of the other one of the capacitor elements 2C is connected to the signal output terminal OUT. The second terminal electrode 12 of the inductor element 2L is connected to the ground terminal GND. The first terminal electrodes 11 of the capacitor element 20, the inductor element 2L, and a resistor element 2R are electrically connected to one another in each of the regions 3gp of the conductor layer 3g. Therefore, the filter 9′ functions as a high-pass filter. In this case, it may be possible to change one of the two capacitor elements 2C to a resistor element. A ferrite bead may be used as the resistor element. In the above explanation, an example is explained in which the low-pass filter or the high-pass filter using at least two of the capacitor element, the inductor element, the resistor element is applied. However, the types of the elements used in the filter and the type of the filter are not limited by the above embodiments.

### Third Modification

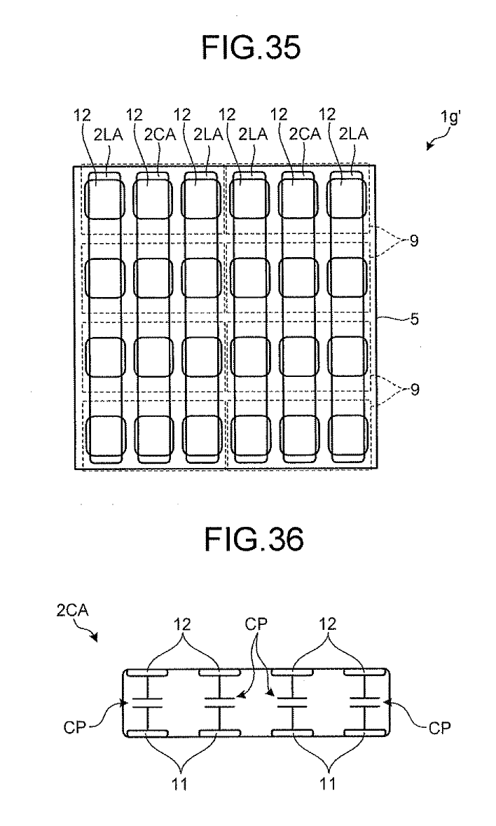

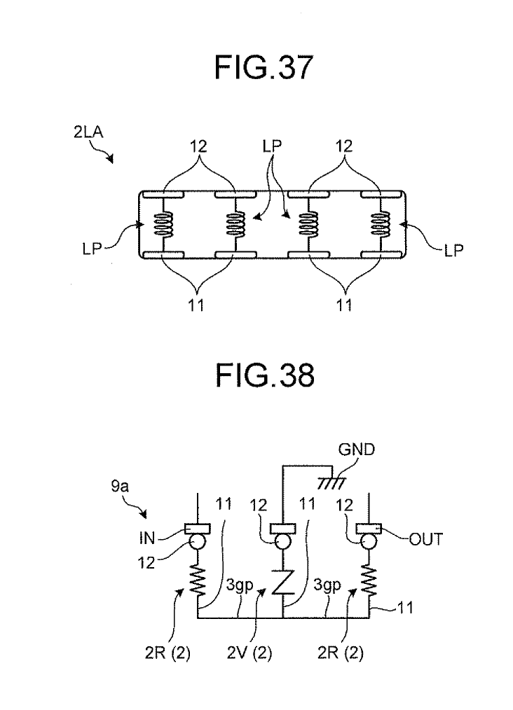

FIG. 35 is a plan view of a composite electronic component according to a third modification of the fourth embodiment. FIG. 36 and FIG. 37 are diagrams illustrating an electronic component included in the composite electronic component according to the third modification of the fourth embodiment. A composite electronic component 1g′ according to the third modification includes a plurality of capacitor arrays 2CA and inductor arrays 2LA as the electronic components and the filters 9 are formed by using these arrays, which are different from the above embodiments or modifications.

As illustrated in FIG. 35, the composite electronic component 1g′ includes two capacitor arrays 2CA and four inductor arrays 2LA. As illustrated in FIG. 36, each of the capacitor arrays 2CA includes four capacitor element portions CP. The four capacitor element portions CP are arranged in line. Each of the capacitor element portions CP includes the first terminal electrode 11 and the second terminal electrode 12. As illustrated in FIG. 37, each of the inductor arrays 2LA includes four inductor element portions LP. The four inductor element portions LP are arranged in line. Each of the inductor element portions LP includes the first terminal electrode 11 and the second terminal electrode 12.

The composite electronic component 1g′ includes the conductor layer 3g, which is included in the composite electronic component 1g of the second modification of the fourth embodiment. Specifically, the composite electronic component 1g′ includes a plurality of the regions 3gp that are electrically isolated from one another by a plurality of the grooves 8. As illustrated in FIG. 35, in the composite electronic component 1g′, the inductor array 2LA, the capacitor array 2CA, the inductor array 2LA are arranged in this order. The first terminal electrodes 11 of the two inductor element portions LP included in the two inductor arrays 2LA and the first terminal electrode 11 of the one capacitor element portion CP included in the one capacitor array 2CA are electrically connected in each of the regions 3gp of the conductor layer 3g. The filter 9 is formed by the two inductor element portions LP and the one capacitor element portions CP, the first terminal electrodes 11 of which are electrically connected to one another in each of the regions 3gp. In this way, the filter 9 can be formed by combining the array electronic components, such as the capacitor array 2CA and the inductor arrays 2LA.

FIG. 38 is a diagram illustrating an equivalent circuit according to a modification of the electronic component group included in the composite electronic component according to the fourth embodiment. In this example, the electronic components 2 included in an electronic component group 9a surrounded by the groove 8 are a varistor element (for example, a chip varistor) 2V and resistor elements 2R. In the electronic component group, the first terminal electrode 11 of the one varistor element 2V and the first terminal electrodes 11 of the two resistor elements 2R are electrically connected to one another in each of the regions 3gp of the conductor layer, and function as a varistor as the predetermined function. In the electronic component group 9a, the second terminal electrode 12 of one of the resistor elements 2R is electrically connected to the signal input terminal IN, and the second terminal electrode 12 of the other one of the resistor elements 2R is electrically connected to the signal output terminal OUT. The second terminal electrode 12 of the varistor element 2V is electrically connected to the ground terminal GND. The composite electronic component of the fourth embodiment may include a plurality of the electronic component group 9a as described above.

As described above, according to the above embodiments and modifications, in addition to the same advantageous effects of the first embodiment, it is possible to incorporate a plurality of electronic component groups, each including a plurality of electronic components combined by the grooves arranged in the conductor layer so as to implement a predetermined function, into one composite electronic component, and it is possible to improve the reliability of each of the electronic component groups. The configurations of the above embodiments and modifications may be applied appropriately to other embodiments.

According to an embodiment of the present invention, it is possible to improve the reliability of the composite electronic component including a plurality of electronic components.

In the composite electronic component, the first terminal electrodes of the electronic components are electrically connected to one another by a conductor layer. Therefore, even when a defect occurs in a certain electronic component, if other electronic components are normal, it is possible to maintain the function as the composite electronic component by the normal electronic components. As a result, it is possible to improve the reliability of the composite electronic component including a plurality of the electronic components.

According to another embodiment of the present invention, it is possible to increase the density of the electronic components arranged in the composite electronic component. Therefore, for example, if capacitors are used as the electronic components, the capacitance of the composite electronic component can be increased. In this case, it is also possible to reduce the size of the composite electronic component 1f the capacitance is the same.

According to still another embodiment of the present invention, it is possible to support a plurality of the electronic components not only by the support but also by the insulating member. Therefore, it is possible to more firmly support the electronic components.

According to still another embodiment of the present invention, the through holes determine the positions of the electronic components, so that the positional accuracy of the electronic components can be improved.

According to still another embodiment of the present invention, electric currents flow in the opposite directions in the adjacent electronic components. As a result, the composite electronic components can reduce an equivalent series inductance (ESL).

According to still another embodiment of the present invention, the composite electronic component can function as a capacitor.

According to still another embodiment of the present invention, it is possible to connect the adjacent capacitor element and resistor element in series. Therefore, it is possible to increase the ESR of the composite electronic component.

According to still another embodiment of the present invention, the composite electronic component can reduce the ESL.

According to still another embodiment of the present invention, it is possible to reduce the number of the electronic components included in the composite electronic component. Therefore, it is possible to improve the operating efficiency in mounting the electronic components on the support.

According to still another embodiment of the present invention, a radiator member can efficiently prevent an increase in the temperature of the composite electronic component.

According to still another embodiment of the present invention, the ESL of each of the electronic components can be reduced, so that the ESL of the entire composite electronic component can be reduced.

In general, the conductor is a good conductor of heat. Therefore, by using the conductor as the support, it becomes possible to more efficiently transfer heat of the electronic components included in the composite electronic component.

According to still another embodiment of the present invention, the support can electrically isolate the first terminal electrodes. Therefore, it is possible to prevent short circuit between the electronic components and a casing housing the circuit substrate or other electronic components mounted on the circuit substrate via the support.

According to still another embodiment of the present invention, the composite electronic component includes a plurality of the electronic component groups, in each of which the first terminal electrodes of a plurality of electronic components are electrically connected, in respective regions divided by a groove in the conductor layer. The composite electronic component can cause the electronic component groups to implement predetermined functions and can improve the reliabilities of the respective electronic component groups.

According to still another embodiment of the present invention, it is possible to obtain the composite electronic component including a plurality of filters.

According to still another embodiment of the present invention, it is possible to obtain the composite electronic component including a plurality of varistors.

The first terminal electrodes of the electronic components mounted on the circuit substrate in the mounting structure of the composite electronic component are electrically connected to one another by the conductor layer. Therefore, even when a defect occurs in a certain electronic component, if other electronic components are normal, it is possible to maintain the function as the composite electronic component by the normal electronic components. As a result, it is possible to improve the reliability of the composite electronic component including a plurality of the electronic components. Furthermore, the second terminal electrodes of the electronic components are connected to the terminals of the circuit substrate such that the polarities of the second terminal electrodes become opposite to each other. Therefore, the directions of electric currents that flow through the adjacent electronic components become opposite to each other. As a result, the mounting structure of the composite electronic component can reduce the ESL.

According to still another embodiment of the present invention, it is possible to connect the adjacent capacitor element and resistor element in series. Therefore, it is possible to increase the ESR of the composite electronic component.

What is claimed is:

1. A composite electronic component comprising:
a plurality of electronic components, each including a first terminal electrode and a second terminal electrode that are arranged on respective opposing surfaces of an element body;
a conductor layer for electrically connecting the first terminal electrodes of the electronic components to one another; and
a support on which the conductor layer is formed, wherein
the second terminal electrodes of the electronic components function as mounting terminal electrodes to be connected to terminals of a circuit substrate.

2. The composite electronic component according to claim 1, wherein the electronic components are arranged in a first direction and in a second direction that is orthogonal to the first direction.

3. The composite electronic component according to claim 1, further comprising an insulating member that is arranged on a surface of the conductor layer and that exposes at least parts of the second terminal electrodes from a side opposite the conductor layer.

4. The composite electronic component according to claim 3, wherein
the insulating member includes through holes that penetrate through the insulating member from the side where the parts of the second terminal electrodes are exposed to the conductor layer, and
the electronic components are arranged inside the through holes, respectively.

5. The composite electronic component according to claim 1, wherein the electronic components are connected to the terminals of the circuit substrate such that the second terminal electrodes of adjacent electronic components become opposite to each other.

6. The composite electronic component according to claim 1, wherein the electronic components are capacitor elements.

7. The composite electronic component according to claim 1, wherein the electronic components include a capacitor element and a resistor element, and the capacitor element and the resistor element are arranged so as to be adjacent to each other.

8. The composite electronic component according to claim 7, wherein the capacitor element and the resistor element are arranged such that the second terminal electrodes of the adjacent capacitor element and resistor element become opposite to each other.

9. The composite electronic component according to claim 1, wherein each of the electronic components is an array electronic component including a plurality of element portions.

10. The composite electronic component according to claim 1, wherein the support includes a radiator member on a side opposite the side where the electronic components are arranged.

11. The composite electronic component according to claim 1, wherein
the element body has a cuboid shape, and
the first terminal electrode and the second terminal electrode are arranged on respective opposing long-side surfaces where an inner electrode is exposed among four long-side surfaces of the element body, the four long-side surfaces connecting two opposing short-side surfaces of the element body.

12. The composite electronic component according to claim 1, wherein the support is a conductor.

13. The composite electronic component according to claim 1, wherein the support is an insulator.

14. The composite electronic component according to claim 13, wherein the conductor includes a groove that surrounds a plurality of adjacent electronic components and that reaches the support.

15. The composite electronic component according to claim 14, wherein the electronic components surrounded by the groove include a capacitor element, an inductor element, or a resistor element, and function as a filter.

16. The composite electronic component according to claim 14, wherein the electronic components surrounded by the groove include a varistor element and a resistor element, and function as a varistor.

17. A mounting structure of a composite electronic component, the composite electronic component comprising:
a plurality of electronic components each including a first terminal electrode and a second terminal electrode that are arranged on respective opposing end surfaces of an element body;
a conductor layer for electrically connecting the first terminal electrodes of the electronic components to one another; and
a support on which the conductor layer is arranged, wherein
the electronic components are connected to terminals of a circuit substrate such that the polarities of the second terminal electrodes become opposite to each other.

18. The mounting structure according to claim 17, wherein
the electronic components include a capacitor element and a resistor element,
the capacitor element and the resistor element are arranged adjacent to each other, and
the adjacent capacitor element and resistor element are connected to the terminals of the circuit substrate such that the polarities of the second terminal electrodes become opposite to each other.
